(19) United States
(12) Patent Application Publication
(10) Pub. No.: US 2025/0349704 A1
(43) Pub. Date: Nov. 13, 2025

(54) THROUGH DIELECTRIC VIA

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Chih-Chao Yang, Glenmont, NY (US)

(21) Appl. No.: 18/657,165

(22) Filed: May 7, 2024

(51) Int. Cl. H01L 23/522; H01L 21/768; H01L 21/8234; H01L 23/48; H01L 23/528; H01L 27/088

(52) U.S. Cl. CPC H01L 23/5226; H01L 21/76877; H01L 21/76898; H01L 23/481; H01L 23/5283; H01L 23/5286; H10D 84/013; H10D 84/0149; H10D 84/038; H10D 84/83

(57) ABSTRACT

Embodiments of present invention provide a semiconductor structure. The semiconductor structure includes a first area having a back-end-of-line (BEOL) region that includes a first set of vias; a metal level with one metal line above the first set of vias; and a second set of vias above the metal level; and a second area having a metal stub, where a bottom surface of the metal stub is substantially aligned with a bottom surface of the first set of vias and a top surface of the metal stub is substantially aligned with either a top surface of the one metal line of the metal level or a top surface of the second set of vias, and where the metal stub has a horizontal width that is at least 10 times larger than a width of the one metal line. A method of forming the semiconductor structure is also provided.

### BACKGROUND

The present application relates to manufacturing of semiconductor integrated circuits. More particularly, it relates to a method of forming a through dielectric via and the structure formed thereby.

As semiconductor industry moves towards smaller node for increased device density, backside power distribution network (BSPDN) is introduced as a mean to enhance the device density. In the application of the BSPDN, one of the key enablers is the connection between the BSPDN and metal levels in the back-end-of-line (BEOL) region at the frontside of the device, and such connection is usually made in the form of a through dielectric via (TIV).

Generally, the through dielectric via has a width that is substantially larger than that of a metal line that it intends to connect. In the process of creating a via opening for the through dielectric via, it becomes increasingly difficult to avoid punching through the metal line.

### SUMMARY

Embodiments of present invention provide a semiconductor structure. The semiconductor structure includes a first area having a transistor with a backside source/drain contact; a metal level with at least one metal line; a first set of vias at a bottom of the metal level; and a second set of vias at a top of the metal line; a second area having a metal stub in a region above a level of the transistor; and a through dielectric via (TIV) extending from a level below the transistor to the metal stub, where a top portion of the TIV is embedded in the metal stub.

In one embodiment, the metal stub has a first height H1 and the top portion of the TIV embedded in the metal stub has a second height H2, with H2 being 20% or more of H1.

In another embodiment, the metal stub has a first horizontal width W1 and the TIV has a second horizontal width W2, with W2 being between about 60% and about 80% of W1.

In yet another embodiment, the metal stub has a first horizontal width W1, the at least one metal line has a width W0, and W1 is at least 10 times larger than W0.

In a further embodiment, the metal stub has a first horizontal width W1, and W1 changes discontinuously along a sidewall of the metal stub.

In one embodiment, a bottom surface of the metal stub is substantially aligned with a bottom surface of the first set of vias.

In another embodiment, a top surface of the metal stub is substantially aligned with either a top surface of the one metal line or a top surface of the second set of vias.

In yet another embodiment, a bottom surface of the TIV is substantially aligned with a bottom surface of the backside source/drain contact of the transistor.

Embodiments of present invention also provide a method of forming a semiconductor structure. The method includes forming a transistor, a metal level with at least one metal line, a first set of vias at a bottom of the metal level, and a second set of vias at a top of the metal level in a first area; forming a metal stub in a second area at a region above a level of the transistor; forming a through dielectric via (TIV) extending from a level below the transistor to the metal stub, embedding a top portion of the TIV in the metal stub.

In one embodiment, forming the metal stub includes forming a first portion of the metal stub during a process of forming the first set of vias; forming a second portion of the metal stub during a process of forming the at least one metal line of the metal level; and forming a third portion of the metal stub during a process of forming the second set of vias.

In another embodiment, forming the first, the second, and the third portion of the metal stub includes forming a horizontal width of the first portion, the second portion, and the third portion that is at least 10 times larger than a width of the at least one metal line.

In yet another embodiment, forming the first portion of the metal stub comprises forming a bottom surface of the first portion to be substantially aligned with a bottom surface of the first set of vias.

According to one embodiment, the method further includes forming a backside source/drain contact of the transistor, and wherein forming the TIV comprises forming a bottom surface of the TIV to be substantially aligned with a bottom surface of the backside source/drain contact.

In one embodiment, the metal stub is embedded in a dielectric layer, and forming the TIV includes creating a via opening in the dielectric layer and partially into the metal stub; and filling the via opening with a conductive material during a process of forming the backside source/drain contact.

In another embodiment, forming the TIV includes forming a horizontal width of the TIV to be between about 60% and about 80% of a horizontal width of the metal stub.

### BRIEF DESCRIPTION OF THE DRAWINGS

The present invention will be understood and appreciated more fully from the following detailed description of embodiments of present invention, taken in conjunction with accompanying drawings of which:

FIGS. 1 to 12 are demonstrative illustrations of cross-sectional views of a semiconductor structure at various steps of manufacturing thereof according to one embodiment of present invention; and

FIG. 13 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

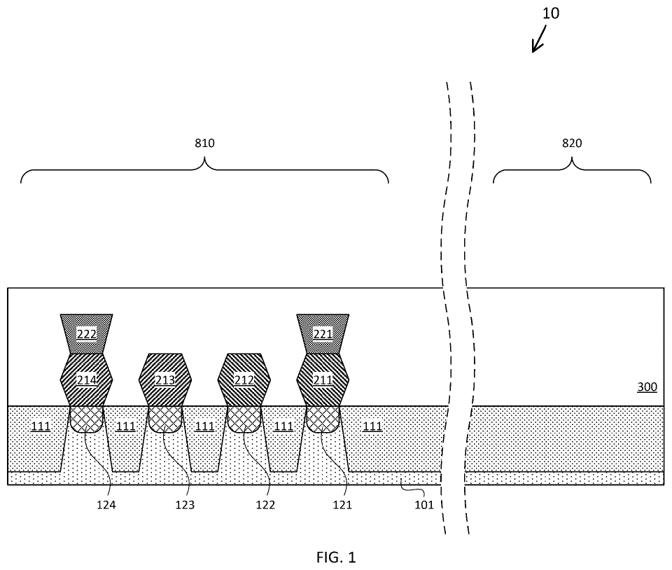

FIG. 1 is a demonstrative illustration of cross-sectional view of a semiconductor structure in a step of manufacturing thereof according to one embodiment of present invention. More specifically, embodiments of present invention provide receiving or forming a semiconductor structure 10 that includes a first area 810 and a second area 820. The first area 810 may not be immediately adjacent to the second area 820, as being demonstratively illustrated by the two dashed curve lines.

In one embodiment, the semiconductor structure 10 may include one or more transistors, in the first area 810, that have one or more source/drain (S/D) regions such as S/D regions 211, 212, 213, and 214. The S/D regions 211, 212, 213, and 214 may be formed on top of a semiconductor substrate 101, and more particularly on top of one or more placeholders 121, 122, 123, and 124 that are embedded in the semiconductor substrate 101. One or more shallow-trench-isolations (STI's) 111 may be formed in the semiconductor substrate 101 separating the one or more transistors.

Further for example, the semiconductor structure 10 may further include one or more MOL contacts such as a first S/D contact 221 and a second S/D contact 222 contacting the S/D regions 211 and 214 respectively. The S/D regions 211, 212, 213, and 214, the first S/D contact 221, and the second S/D contact 222 may be embedded in a first dielectric layer 300. The first dielectric layer 300 may be a layer of silicon-nitride (SIN), silicon-oxide (SiO), or other dielectric materials.

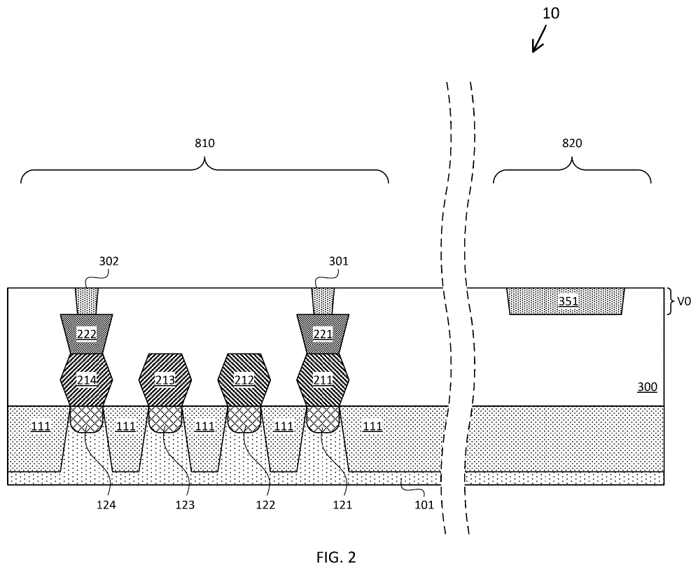

FIG. 2 is a demonstrative illustration of cross-sectional view of a semiconductor structure in a step of manufacturing thereof according to one embodiment of present invention. More specifically, following the step illustrated in FIG. 1, embodiments of present invention provide creating one or more via openings in the dielectric layer 300 in the first area 810 to expose top surfaces of the first and the second S/D contact 221 and 222. In one embodiment, the via openings may be created through, for example, a lithographic patterning process followed by a selective etch process such as a reactive-ion-etch (RIE) process. Conductive materials, such as copper (Cu), aluminum (Al), cobalt (Co), tungsten (W) to name a few, may be deposited in the via openings to form, for example, a first via 301 and a second via 302 of a first set of vias. The first set of vias may be at a first via level such as V0. The deposition of the conductive materials may be made through, for example, a chemical-vapor-deposition (CVD) process, a physical-vapor-deposition (PVD) process, an atomic-layer-deposition (ALD) process, and/or other currently existing or future developed deposition techniques. The first via 301 may be made to be in contact with the first S/D contact 221 and the second via 302 may be made to be in contact with the second S/D contact 222.

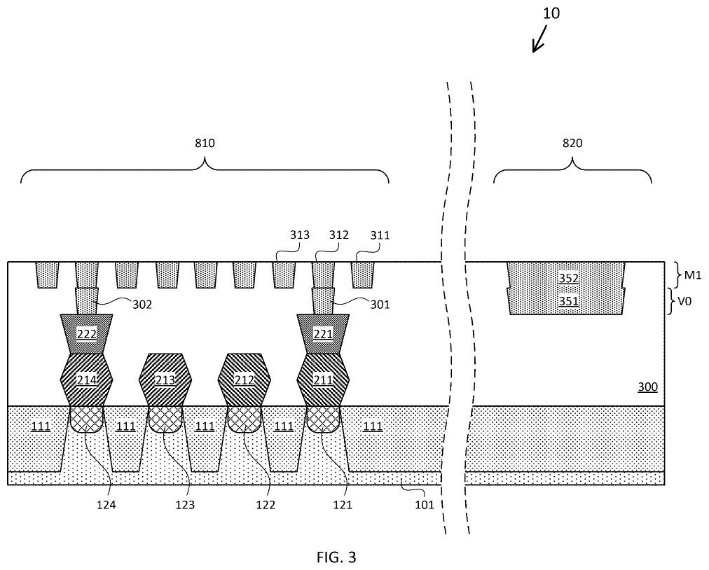

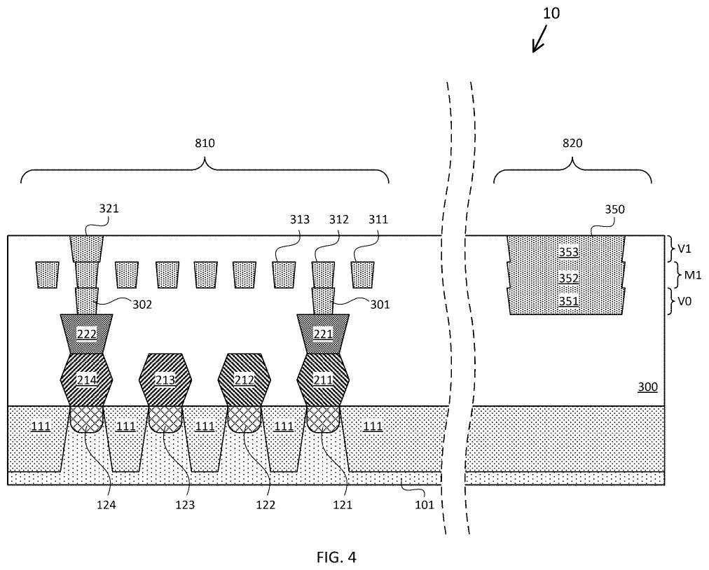

Embodiments of present invention further provide, during the process of forming the first set of vias such as the first via 301 and the second via 302, forming a first portion 351 of a metal stub 350 (see FIG. 4) in the second area 820 of the semiconductor structure 10. More particularly, a first opening may be created, in the second area 820 of the first dielectric layer 300, during the process of creating via openings for the first via 301 and the second via 302. The first opening may be created to have a width that is, for example, at least 10 times larger than a width of a metal line, such as a second metal line 312 (see FIG. 3) to be formed later on top of the first via 301 and/or the second via 302. Conductive materials such as those used in forming the first via 301 and the second via 302 may then be deposited, during the process of filling the via openings for the first via 301 and the second via 302 in the first area 810, in the first opening to form the first portion 351 of the metal stub 350. By the nature of the process, a bottom surface of the first portion 351 of the metal stub 350, that is a bottom surface of the metal stub 350, may be substantially aligned, horizontally, with a bottom surface of the first via 301 and the second via 302. On the other hand, the first portion 351 of the metal stub 350 may have a width that is at least 10 times larger than a width of the second metal line 312. For example, the width of the second metal line 312 may range from about 20 nm to about 40 nm, and the width of the first portion 351 of the metal stub 350 may range from about 200 nm to about 500 nm.

FIG. 3 is a demonstrative illustration of cross-sectional view of a semiconductor structure in a step of manufacturing thereof according to one embodiment of present invention. More specifically, following the step illustrated in FIG. 2, embodiments of present invention provide forming one or more metal lines of a metal level such as, for example, a metal level M1 on top of the first via 301 and the second via 302 of the first via level V0.

In doing so, one embodiment of present invention provides depositing a second dielectric layer on top of the first dielectric layer 300, covering the first and the second via 301 and 302 of the first via level V0 and the first portion 351 of the metal stub 350. The second dielectric layer may include a material that is same as or different from that of the first dielectric layer 300. One or more openings such as trench openings may be created in the second dielectric layer, with one or more of which exposing the first via 301 and the second via 302. Conductive materials, such as those described above including Cu, Al, Co, W, may be deposited into the one or more trench openings to form one or more metal lines of the metal level M1. As being demonstratively illustrated in FIG. 3, the one or more metal lines may include, for example, a first metal line 311, a second metal line 312, and a third metal line 313.

In the meantime, during the process of forming the one or more metal lines, a second opening may be created, in the second area 820 of the second dielectric layer, that exposes a top surface of the first portion 351 of the metal stub 350. Like the first opening, the second opening may be created to have a width that is, for example, at least 10 times larger than a width of the one or more metal lines such as, for example, a width of the second metal line 312. Conductive materials such as those used in forming the first, the second, and the third metal line 311, 312, and 313 may then be deposited, during the process of filling the trench openings in the first area 810, in the second opening to form a second portion 352 of the metal stub 350. The second portion 352 of the metal stub 350 may be directly on top of the first portion 351 of the metal stub 350 and may have a width that is at least 10 times larger than the width of the second metal line 312. The first portion 351 and the second portion 352 may be substantially, but not fully, aligned with each other. There may be a discontinuous change in width between the first portion 351 and the second portion 352 of the metal stub 350.

In another embodiment, the first, the second, and the third metal lines 311, 312, and 313 of the metal level M1 as well as the second portion 352 of the metal stub 350 may be formed through a subtractive patterning process. More particularly, a layer of conductive material, such as Cu, Al, Co, and W as those described above, may first be deposited on top of the first dielectric layer 300, optionally via some diffusion barrier layer. This conductive material lay may then be patterned, for example, through a lithographic patterning process followed by a selective etch process, and transformed into the first, the second, and the third metal lines 311, 312, and 313 and the second portion 352 of the metal stub 350.

In yet another embodiment, the first via 301, the second via 302, and the first portion 351 of the metal stub 350 may be formed together with the first metal line 311, the second metal line 312, the third metal line 313, and the second portion 352 of the metal stub 350 in a damascene process. More particularly, via openings and trench openings may be created in a same patterning process in both the first dielectric layer 300 and the second dielectric layer on top thereof. Conductive materials may subsequently be deposited in the via openings as well as the trench openings in forming both the first set of vias V0 and the one or more metal lines of the metal level M1.

FIG. 4 is a demonstrative illustration of cross-sectional view of a semiconductor structure in a step of manufacturing thereof according to one embodiment of present invention. More specifically, following the step illustrated in FIG. 3, embodiments of present invention provide forming a second set of vias on top of the one or more metal lines of the metal level M1. More particularly, a third dielectric layer may be deposited on top of the second dielectric layer covering the first, the second, the third metal line 311, 312, 313 and the second portion 352 of the metal stub 350. One or more via openings may be created in the third dielectric layer that expose one or more of the one or more metal lines in the second dielectric layer. Conductive materials such as those described above may then be deposited in the one or more via openings to form the second set of vias, which may be at a second via level V1. For example, the second via level M1 may include a first via 321, which may be formed directly on top of a metal line that is in contact with the second via 302 of the first via level V0.

Depending on the need for a thickness of the metal stub 350 that is sufficient to prevent punch through in subsequent etch process, embodiments of present invention may provide, optionally, forming a third portion 353 of the metal stub 350 during the process of forming the second set of vias. The third portion 353 of the metal stub 350 may be formed in a manner substantially similar to that of forming the first portion 351 of the metal stub 350. The third portion 353 may have a width that is at least 10 times larger than a width of the one or more metal lines such as that of the second metal line 312, and a top surface of the third portion 353, which is a top surface of the metal stub 350, may be substantially aligned with, horizontally, a top surface of the first via 321 of the second set of vias at the second via level V1. The first portion 351, the second portion 352, and the third portion 353 may together form the metal stub 350 in the second area 820 of the semiconductor structure 10. The first dielectric layer 300 and the second and third dielectric layers may collectively be referred to as a dielectric layer.

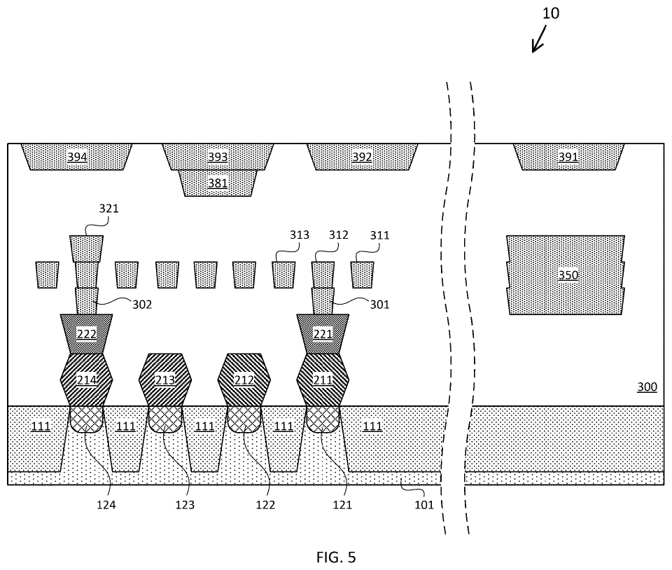

FIG. 5 is a demonstrative illustration of cross-sectional view of a semiconductor structure in a step of manufacturing thereof according to one embodiment of present invention. More specifically, following the step illustrated in FIG. 4, embodiments of present invention provide forming additional via and metal levels, alternately, on top of the via level V1 and the metal stub 350. For example, as being demonstratively illustrated in FIG. 5, the additional via and metal levels may include a via level including a via 381 and a metal level including metal lines 391, 392, 393, and 394. The additional via and metal levels may also be embedded in the dielectric layer 300. The various via levels and metal levels together form a back-end-of-line (BEOL) region above the one or more transistors. The metal stub 350 may be embedded in the BEOL region and surrounded by the dielectric layer 300.

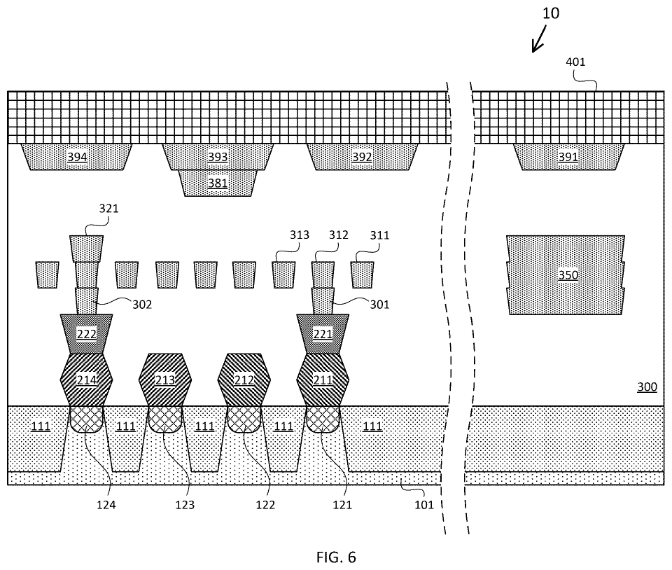

FIG. 6 is a demonstrative illustration of cross-sectional view of a semiconductor structure in a step of manufacturing thereof according to one embodiment of present invention. More specifically, following the step illustrated in FIG. 5, embodiments of present invention provide attaching a handling wafer 401 to the BEOL structure such as the semiconductor structure 10 may be flipped upside-down for further processing from a backside of the structure.

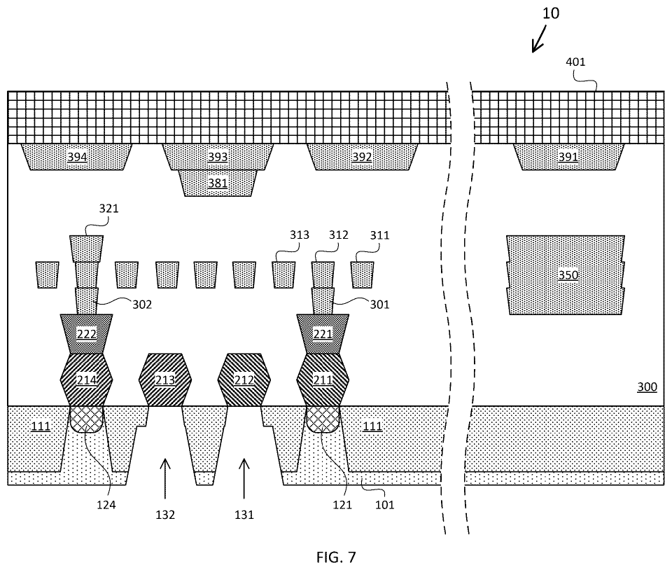

FIG. 7 is a demonstrative illustration of cross-sectional view of a semiconductor structure in a step of manufacturing thereof according to one embodiment of present invention. More particularly, following the step illustrated in FIG. 6, embodiments of present invention provide forming backside S/D contacts by creating opening from backside of the semiconductor structure 10 to expose bottom surfaces of the S/D regions. Hereinafter, processing of the semiconductor structure 10 is performed from the backside of the semiconductor substrate 101 and the description will be provided in such a manner with an upside-down flipped semiconductor structure 10 in mind. Nevertheless, for the convenience of illustration, drawings of FIGS. 7-12 may continue to be provided in an upside-up fashion.

For example, embodiments of present invention provide creating a first backside contact opening 131 and a second backside contact opening 132 in the semiconductor substrate 101. The first and the second backside contact opening 131 and 132 may expose the placeholders 122 and 123 respectively, and the exposed placeholders 122 and 123 may be selectively removed subsequently. Embodiments of present invention may therefore expose the bottom surfaces of the S/D regions 212 and 213.

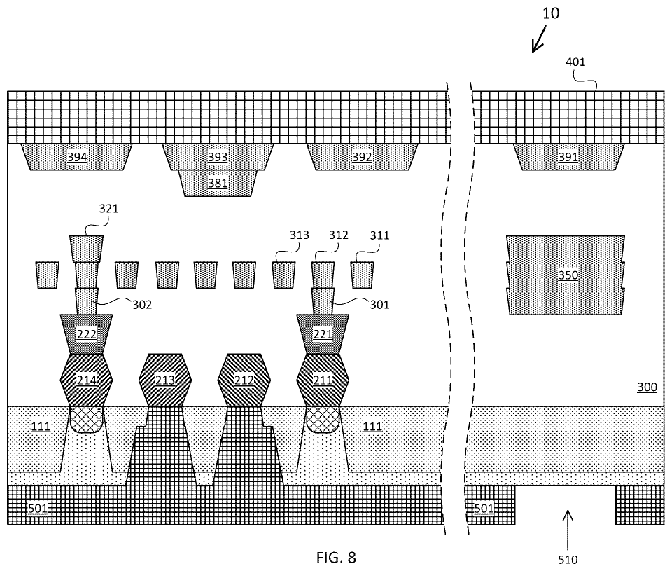

FIG. 8 is a demonstrative illustration of cross-sectional view of a semiconductor structure in a step of manufacturing thereof according to one embodiment of present invention. More particularly, following the step illustrated in FIG. 7, embodiments of present invention provide protecting the first and the second backside contact opening 131 and 132 from a subsequent processing step by filling the first and the second backside contact opening 131 and 132 with a sacrificial material. For example, in one embodiment embodiments of present invention provide forming a mask 501 on top of the semiconductor substrate 101 and using the material of the mask 501 to fill the first and the second backside contact opening 131 and 132 thereby protecting the second and the third source/drain region 212 and 213.

On the other hand, the mask 501 may be a soft mask formed by, for example, an organic planarization layer (OPL) although embodiments of present invention are not limited in this aspect and other types of soft mask or even hard mask may be used as well. The mask 501 may have an opening 510 that is strategically aligned with the underneath metal stub 350. The opening 510 may have a width that is about, for example, 60% to 80% of the width of the metal stub 350. Embodiments of present invention apply the opening 510 in creating a via opening that will land on and expose the metal stub 350, as being described below in more details.

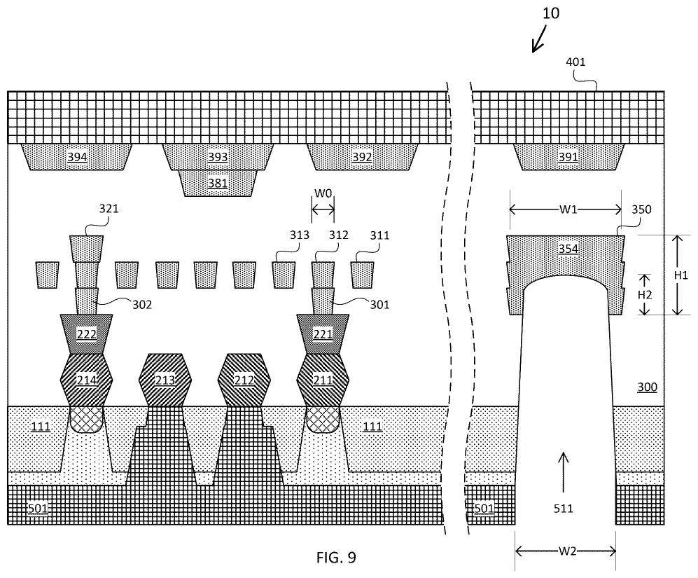

FIG. 9 is a demonstrative illustration of cross-sectional view of a semiconductor structure in a step of manufacturing thereof according to one embodiment of present invention. More particularly, following the step illustrated in FIG. 8, embodiments of present invention provide etching, selectively through the opening 510 of the mask 501, the semiconductor substrate 101, the shallow-trench-isolation 111, and the first dielectric layer 300. Because of the size of the opening 510, which is about 6 to 10 times of the width of the metal lines such as a width W0 of the second metal line 312 of the metal level M1, the selective etch process may create a via opening 511 that, through the first dielectric layer 300, may over-etch into the metal stub 350, resulting in an etched metal stub 354. In other words, the via opening 511 may be over-etched partially into the metal stub 350. In one embodiment, the portion of the opening 511 over-etched into the metal stub 350 may have a height H2 that may be 20% or more of a total height H1 of the metal stub 350. For example, the metal stub 350 as is illustrated in FIG. 9 spans across the first via level V0, the metal level M1, and the second via level V1 to have a total height around, for example, 120 nm such as ranging from about 100 nm to about 150 nm. In this case, the over-etch into the metal stub 350 may have height as high as 30 nm.

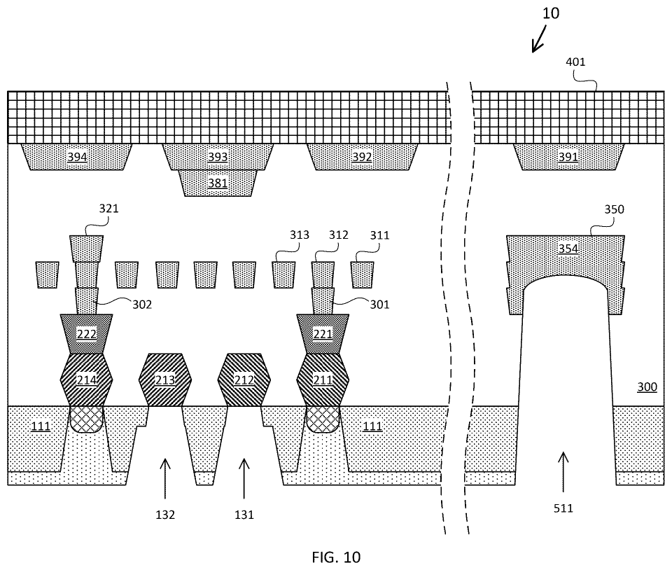

FIG. 10 is a demonstrative illustration of cross-sectional view of a semiconductor structure in a step of manufacturing thereof according to one embodiment of present invention. More particularly, following the step illustrated in FIG. 9, embodiments of present invention provide removing the mask 501 from the top of the semiconductor substrate 101 and from the first and the second backside contact opening 131 and 132 to expose or re-expose the second and the third source/drain regions 212 and 213. The removal of the mask 501 may be made through, for example, a reactive-ion-etch (RIE) and/or other selective lifting process.

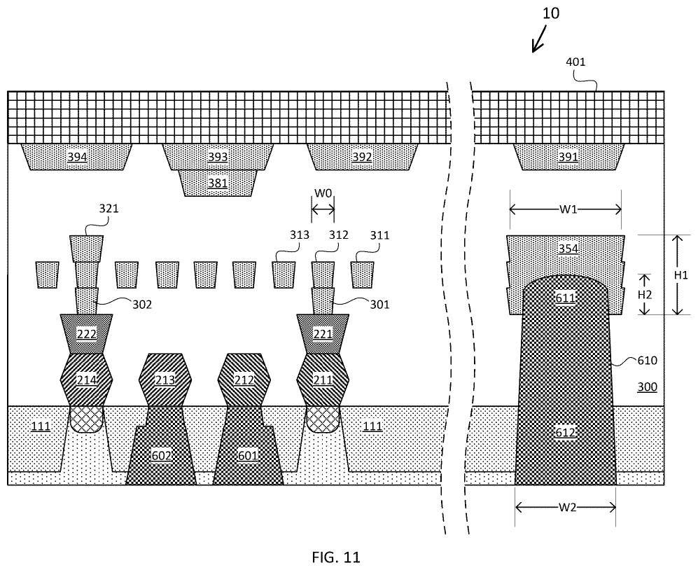

FIG. 11 is a demonstrative illustration of cross-sectional view of a semiconductor structure in a step of manufacturing thereof according to one embodiment of present invention. More particularly, following the step illustrated in FIG. 10, embodiments of present invention provide filling, for example through a deposition process, the first and the second backside contact opening 131 and 132 with a conductive material to form a first and a second backside contact 601 and 602. During the same deposition process, the same conductive material may be used to fill the opening 511 to form a through dielectric via (TIV) 610. The conductive material used in forming the TIV 610, as well as the first and the second backside contact 601 and 602, may include, for example, Cu, Al, Co, W, and other suitable materials.

In one embodiment, the metal stub 350 may have a height H1, for example between about 100 nm and about 150 nm. The TIV 610 may have a top portion 611 and a bottom portion 612, with the top portion 611 being formed inside the over-etch of the metal stub 350 to have a height H2 that is about 20% or more of H1. The thickness H1 is sufficient enough to ensure that the creation of the opening 511 does not punch through the metal stub 350. The moderate over-etch enables the creation of the top portion 611 of the TIV 610. The top portion 611 is embedded in, thereby having an increased contact surface area between the etched metal stub 354 and the TIV 610 to reduce the overall contact resistance there in-between.

In another embodiment, the metal stub 350 may have a first horizontal width W1, which may be the smallest one among widths of the first portion 351, the second portion 352, and the third portion 353 of the metal stub 350. The first portion 351, the second portion 352, and the third portion 353 may have different widths, in some cases may be slightly, resulting the first horizontal width W1 of the metal stub 350 to change discontinuously along sidewalls of the metal stub 350. The discontinuous changes may happen at locations with the level of locations corresponding to either the top surface or the bottom surface of the metal level M1 in the first area 810 of the semiconductor structure 10.

In the meantime, the TIV 610 may have a second horizontal width W2 and W2 may range, for example, from about 60% to about 80% of the first horizontal width W1 of the metal stub 350. Having W2 being about 60% to about 80% of W1 is important and critical since it ensures that the TIV will fully land on the metal stub 350 while in the meantime lowers resistance of the TIV 610 as much as possible. On the other hand, the first horizontal width W1 may be at least 10 times larger than a width W0 of a metal line such as the second metal line 312 of the metal level M1.

After the deposition of the conductive material in forming the TIV 610 and the first and the second backside contact 601 and 602, a chemical-mechanical-polishing (CMP) process may be applied to remove excess conductive materials above the semiconductor substrate 101 and planarize a top surface of the conductive materials, thereby creating a bottom surface of the TIV 610 that is substantially aligned, horizontally, with bottom surfaces of the first backside contact 601 and the second backside contact 602.

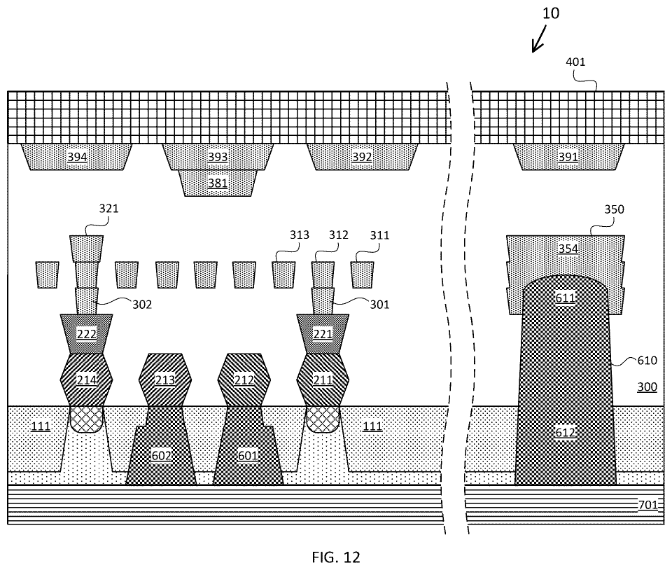

FIG. 12 is a demonstrative illustration of cross-sectional view of a semiconductor structure in a step of manufacturing thereof according to one embodiment of present invention. More particularly, following the step illustrated in FIG. 11, embodiments of present invention provide forming additional backside structures such as, for example, a backside power distribution network (BSPDN) 701 underneath the first and the second backside contact 601 and 602 and the TIV 610.

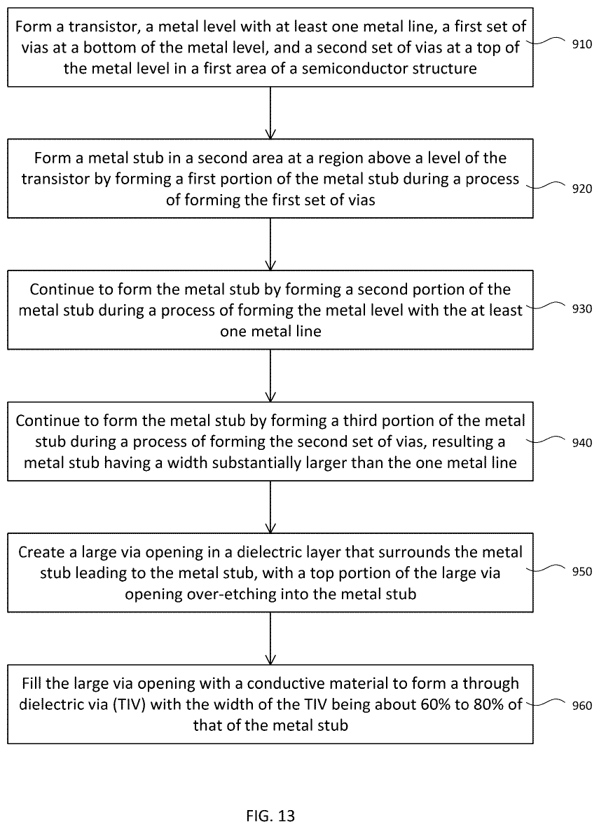

FIG. 13 is a demonstrative illustration of a flow-chart of a method of manufacturing a semiconductor structure according to embodiments of present invention. The method includes (910) forming a transistor, a metal level with at least one metal line, a first set of vias at a bottom of the metal level, and a second set of vias at a top of the metal level in a first area of a semiconductor structure; (920) forming a metal stub in a second area of the semiconductor structure and at a region above a level of the transistor by forming a first portion of the metal stub during a process of forming the first set of vias; (930) continuing to form the metal stub by forming a second portion of the metal stub during a process of forming the metal level with the at least one metal line; (940) continuing to form the metal stub by forming a third portion of the metal stub during a process of forming the second set of vias, resulting a metal stub having a width substantially larger than the one metal line; (950) creating a large via opening in a dielectric layer that surrounds the metal stub leading to the metal stub, with a top portion of the large via opening over-etching into the metal stub; and (960) filling the large via opening with a conductive material to form a through dielectric via (TIV) with the width of the TIV, for example, being about 60% to 80% of that of the metal stub.

Various examples may possibly be described by one or more of the following features in the following numbered clauses:

Clause 1: A semiconductor structure comprising: a first area having a transistor with a backside source/drain contact; a metal level with at least one metal line; a first set of vias at a bottom of the metal level; and a second set of vias at a top of the metal line; a second area having a metal stub in a region above a level of the transistor; and a through dielectric via (TIV) extending from a level below the transistor to the metal stub, wherein a top portion of the TIV is embedded in the metal stub.

Clause 2: The semiconductor structure of clause 1, wherein the metal stub has a first height H1 and the top portion of the TIV embedded in the metal stub has a second height H2, with H2 being 20% or more of H1.

Clause 3: The semiconductor structure of clause 1, wherein the metal stub has a first horizontal width W1 and the TIV has a second horizontal width W2, with W2 being between about 60% and about 80% of W1.

Clause 4: The semiconductor structure of clause 1, wherein the metal stub has a first horizontal width W1, the at least one metal line has a width W0, and W1 is at least 10 times larger than W0.

Clause 5: The semiconductor structure of clause 1, wherein the metal stub has a first horizontal width W1, and W1 changes discontinuously along a sidewall of the metal stub.

Clause 6: The semiconductor structure of clause 1, wherein a bottom surface of the metal stub is substantially aligned with a bottom surface of the first set of vias.

Clause 7: The semiconductor structure of clause 1, wherein a top surface of the metal stub is substantially aligned with either a top surface of the one metal line or a top surface of the second set of vias.

Clause 8: The semiconductor structure of clause 1, wherein a bottom surface of the TIV is substantially aligned with a bottom surface of the backside source/drain contact of the transistor.

Clause 9: A method of forming a semiconductor structure comprising: forming a transistor, a metal level with at least one metal line, a first set of vias at a bottom of the metal level, and a second set of vias at a top of the metal level in a first area; forming a metal stub in a second area at a region above a level of the transistor; forming a through dielectric via (TIV) extending from a level below the transistor to the metal stub, embedding a top portion of the TIV in the metal stub.

Clause 10: The method of clause 9, wherein forming the metal stub comprises forming a first portion of the metal stub during a process of forming the first set of vias; forming a second portion of the metal stub during a process of forming the at least one metal line of the metal level; and forming a third portion of the metal stub during a process of forming the second set of vias.

Clause 11: The method of clause 10, wherein forming the first, the second, and the third portion of the metal stub comprises forming a horizontal width of the first portion, the second portion, and the third portion that is at least 10 times larger than a width of the at least one metal line.

Clause 12: The method of clause 10, wherein forming the first portion of the metal stub comprises forming a bottom surface of the first portion to be substantially aligned with a bottom surface of the first set of vias.

Clause 13: The method of clause 9, further comprising forming a backside source/drain contact of the transistor, and wherein forming the TIV comprises forming a bottom surface of the TIV to be substantially aligned with a bottom surface of the backside source/drain contact.

Clause 14: The method of clause 13, wherein the metal stub is embedded in a dielectric layer, and wherein forming the TIV comprises creating a via opening in the dielectric layer and partially into the metal stub; and filling the via opening with a conductive material during a process of forming the backside source/drain contact.

Clause 15: The method of clause 14, wherein forming the TIV comprises forming a horizontal width of the TIV to be between about 60% and about 80% of a horizontal width of the metal stub.

Clause 16: A semiconductor structure comprising: a first area having a back-end-of-line (BEOL) region, the BEOL region including a first set of vias; a metal level with at least one metal line above the first set of vias; and a second set of vias above the metal level; and a second area having a metal stub, wherein a bottom surface of the metal stub is substantially aligned with a bottom surface of the first set of vias and a top surface of the metal stub is substantially aligned with either a top surface of the at least one metal line of the metal level or a top surface of the second set of vias, and wherein the metal stub has a first horizontal width that is at least 10 times larger than a width of the at least one metal line.

Clause 17: The semiconductor structure of clause 16, further comprising a through dielectric via (TIV) having a top portion thereof embedded in the metal stub, wherein the metal stub has a first height and the top portion of the TIV embedded in the metal stub has a second height, and the second height is about 20% or more of the first height.

Clause 18: The semiconductor structure of clause 17, wherein the TIV has a second horizontal width that is about 60% to 80% of the first horizontal width of the metal stub.

Clause 19: The semiconductor structure of clause 17, wherein the first area further comprises a transistor and a backside source/drain contact underneath the transistor, and wherein a bottom surface of the TIV is substantially aligned with a bottom surface of the backside source/drain contact underneath the transistor.

Clause 20: The semiconductor structure of clause 16, wherein sidewalls of the metal stub have discontinuous changes at locations, a level of the locations corresponds to either the top surface or a bottom surface of the at least one metal line of the metal level in the first area.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first area having a transistor with a backside source/drain contact; a metal level with at least one metal line; a first set of vias at a bottom of the metal level; and a second set of vias at a top of the metal line;
a second area having a metal stub in a region above a level of the transistor; and
a through dielectric via (TIV) extending from a level below the transistor to the metal stub,
wherein a top portion of the TIV is embedded in the metal stub.

2. The semiconductor structure of claim 1, wherein the metal stub has a first height H1 and the top portion of the TIV embedded in the metal stub has a second height H2, with H2 being 20% or more of H1.

3. The semiconductor structure of claim 1, wherein the metal stub has a first horizontal width W1 and the TIV has a second horizontal width W2, with W2 being between about 60% and about 80% of W1.

4. The semiconductor structure of claim 1, wherein the metal stub has a first horizontal width W1, the at least one metal line has a width W0, and W1 is at least 10 times larger than W0.

5. The semiconductor structure of claim 1, wherein the metal stub has a first horizontal width W1, and W1 changes discontinuously along a sidewall of the metal stub.

6. The semiconductor structure of claim 1, wherein a bottom surface of the metal stub is substantially aligned with a bottom surface of the first set of vias.

7. The semiconductor structure of claim 1, wherein a top surface of the metal stub is substantially aligned with either a top surface of the one metal line or a top surface of the second set of vias.

8. The semiconductor structure of claim 1, wherein a bottom surface of the TIV is substantially aligned with a bottom surface of the backside source/drain contact of the transistor.

9. A method of forming a semiconductor structure comprising:
forming a transistor, a metal level with at least one metal line, a first set of vias at a bottom of the metal level, and a second set of vias at a top of the metal level in a first area;
forming a metal stub in a second area at a region above a level of the transistor;
forming a through dielectric via (TIV) extending from a level below the transistor to the metal stub, embedding a top portion of the TIV in the metal stub.

10. The method of claim 9, wherein forming the metal stub comprises forming a first portion of the metal stub during a process of forming the first set of vias; forming a second portion of the metal stub during a process of forming the at least one metal line of the metal level; and forming a third portion of the metal stub during a process of forming the second set of vias.

11. The method of claim 10, wherein forming the first, the second, and the third portion of the metal stub comprises forming a horizontal width of the first portion, the second portion, and the third portion that is at least 10 times larger than a width of the at least one metal line.

12. The method of claim 10, wherein forming the first portion of the metal stub comprises forming a bottom surface of the first portion to be substantially aligned with a bottom surface of the first set of vias.

13. The method of claim 9, further comprising forming a backside source/drain contact of the transistor, and wherein forming the TIV comprises forming a bottom surface of the TIV to be substantially aligned with a bottom surface of the backside source/drain contact.

14. The method of claim 13, wherein the metal stub is embedded in a dielectric layer, and wherein forming the TIV comprises creating a via opening in the dielectric layer and partially into the metal stub; and filling the via opening with a conductive material during a process of forming the backside source/drain contact.

15. The method of claim 14, wherein forming the TIV comprises forming a horizontal width of the TIV to be between about 60% and about 80% of a horizontal width of the metal stub.

16. A semiconductor structure comprising:
a first area having a back-end-of-line (BEOL) region, the BEOL region including a first set of vias; a metal level with at least one metal line above the first set of vias; and a second set of vias above the metal level; and
a second area having a metal stub,
wherein a bottom surface of the metal stub is substantially aligned with a bottom surface of the first set of vias and a top surface of the metal stub is substantially aligned with either a top surface of the at least one metal line of the metal level or a top surface of the second set of vias, and wherein the metal stub has a first horizontal width that is at least 10 times larger than a width of the at least one metal line.

17. The semiconductor structure of claim 16, further comprising a through dielectric via (TIV) having a top portion thereof embedded in the metal stub, wherein the metal stub has a first height and the top portion of the TIV embedded in the metal stub has a second height, and the second height is about 20% or more of the first height.

18. The semiconductor structure of claim 17, wherein the TIV has a second horizontal width that is about 60% to 80% of the first horizontal width of the metal stub.

19. The semiconductor structure of claim 17, wherein the first area further comprises a transistor and a backside source/drain contact underneath the transistor, and wherein a bottom surface of the TIV is substantially aligned with a bottom surface of the backside source/drain contact underneath the transistor.

20. The semiconductor structure of claim 16, wherein sidewalls of the metal stub have discontinuous changes at locations, a level of the locations corresponds to either the top surface or a bottom surface of the at least one metal line of the metal level in the first area.
